(19) United States
(12) Patent Application Publication
(10) Pub. No.: US 2010/0301454 A1
(43) Pub. Date: Dec. 2, 2010

(54) LATTICE MATCHED MULTI-JUNCTION PHOTOVOLTAIC AND OPTOELECTRONIC DEVICES

(76) Inventors: Yong-Hang Zhang, Scottsdale, AZ (US); Shade R. Johnson, Chandler, AZ (US); Shui-Qing Yu, Tempe, AZ (US); Ding Ding, Tempe, AZ (US); Songnan Wu, Tempe, AZ (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/743,113

(22) PCT Filed: Nov. 10, 2008
(86) PCT No.: PCT/US08/82998

§ 371 Date: Aug. 17, 2010

Related U.S. Application Data
(60) Provisional application No. 60/989,355, filed on Nov. 20, 2007.

(51) Int. Cl. H01L 29/22; H01L 29/20; H01L 21/20; H01L 21/36

(52) U.S. Cl. 257/614; 257/615; 438/478; 257/E29.089; 257/E29.094; 257/E21.09; 257/E21.461

(57) ABSTRACT

The present invention provides semiconductor structures comprising a substrate and at least three III-V and/or II-VI multi junction building blocks, each comprising a p-n junction having at least two alloy layers, formed over the substrate, provided at least one multi-junction building block comprises II-VI alloy layers. Further described are methods for preparing semiconductor structures utilizing a sacrificial or etch-stop ternary III-V alloy layer over an III-V substrate.

### CROSS-REFERENCE TO RELATED APPLICATIONS

This application claims the benefit of the filing date, under 35 U.S.C. §119(e), of U.S. Provisional Application Ser. No. 60/989,355 filed 20 Nov. 2007, which is hereby incorporated by reference in its entirety.

### FIELD OF THE INVENTION

The present invention relates to multilayer semiconductor structures comprising III-V and II-VI alloys, methods for their preparation, and uses thereof.

### BACKGROUND OF THE INVENTION

Currently, 75% of the conventional solar panel cost is the Si wafers and related wafer processing. With a potential concentration ratio of 500-1000 and double the efficiency over conventional single junction cells, the use of concentrator multi junction solar cell technologies will dramatically reduce the fraction of the wafer cost for solar panels, which will solve the semiconductor materials bottleneck and lower the overall cost for electricity generation using PV cells.

State-of-the-art GaInP/(In)GaAs/Ge 3-junction solar cells have demonstrated a record 40.7% conversion efficiency under 240 suns concentration and have entered terrestrial concentrator applications. To further reduce the cost, it is highly desirable to develop PV cells with even higher energy conversion efficiency for both terrestrial and space applications.

It is commonly understood that one would not gain much in conversion efficiency when the number of junctions used in tandem cells is increased beyond 5. However, a practical tandem cell consists of not only PV junctions but also tunnel junctions, contact layers, and metal ohmic contacts. The total resistance of all these layers generates additional energy loss, namely Joule heating. By taking a more complete device structure into account that includes all of the important losses, we conclude that PV cells will suffer substantially less efficiencies reduction from the detailed balance limit if more junctions (>5) are used. The main reason for this is the Joule heating generated by the overall series resistance is proportional to the square of the total current, i.e. I²R (i.e., the smaller the number of junctions, the greater the current). For example, in a practical 3-junction cell, the current can reach several A/cm² under concentrated sunlight. When one uses 6 junctions instead, the open circuit voltage (V_{OC}) almost doubles and the current is reduced approximately to half, resulting in one fourth of the Joule heat compared to a 3-junction cell.

These results provide an important design rule for the multi junction solar cells: More junctions need to be used to increase the V_{OC} and reduce the current in the next-generation multi junction solar cell designs. The GaAs or Ge substrate based material system has not been able to offer higher conversion efficiency due to a lack of high-quality near-lattice-matched materials with the optimally spaced bandgaps. Similar multilayer structures can also be designed for multi-color light emitting devices and photodetectors. Those devices can cover a much broader light emission spectrum or light detection bandwidth.

### SUMMARY OF THE INVENTION

In a first aspect, the invention provides a semiconductor structure comprising a substrate and at least three multi junction building blocks formed over the substrate, wherein the substrate is a III-V substrate or a II-VI substrate; and each multi junction building block independently comprises a p-n junction having at least two alloy layers, wherein the alloy layers are independently III-V or II-VI alloy layers, wherein one alloy layer is p-doped and the other alloy layer is n-doped, provided at least one multi-junction building block comprises II-VI alloy layers.

In a second aspect, the invention provides methods for preparing a semiconductor structure comprising preparing an etch-stop ternary III-V alloy layer over an III-V substrate; preparing at least three multi junction building blocks over the etch-stop layer, wherein each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers; removing the substrate; and removing the etch-stop alloy layer.

In a third aspect, the invention provides a semiconductor structure prepared according the methods of the second aspect.

In a fourth aspect, the invention provides a semiconductor structure comprising at least two multi junction building blocks, wherein each multi junction building block independently comprises a p-n junction having at least two alloy layers, wherein the alloy layers are independently III-V or II-VI alloy layers, wherein one alloy layer is p-doped and the other alloy layer is n-doped, provided at least one multi-junction building block comprises II-VI alloy layers.

In a fifth aspect, the invention provides methods for preparing a semiconductor structure comprising forming at least three multi junction building blocks over a substrate, wherein the substrate is a III-V substrate or a II-VI substrate; and each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers.

### BRIEF DESCRIPTION OF THE DRAWINGS

FIG. 1 is an illustration of an embodiment of the semiconductor structures of the invention.

FIG. 2 is an illustration of another embodiment of the semiconductor structures of the invention having two alloy layers per multi junction building block.

FIG. 3 is an illustration of an embodiment of a method of the invention for preparing substrate-free semiconductor structures.

FIG. 4 is an illustration of an embodiment of the substrate-free semiconductor structures of the invention.

FIG. 5 is another illustration of an embodiment of the substrate-free semiconductor structures of the invention having two alloy layers per multi junction building block.

FIG. 6a shows the simulated efficiency of a practical four junction solar cell under the AM0 solar spectrum, as a function of solar concentration for each individual subcell in Example 3.

FIG. 6b shows the simulated efficiency of a practical four-junction solar cell under the AM0 solar spectrum, as a function of solar concentration for the entire four-junction solar cell of Example 3.

FIG. 7a is a schematic layer structure of a proposed 5-junction PV cell design.

FIG. 7b is a schematic diagram of the band alignment at the heterointerfaces together with the tunnel junctions for the proposed 5-junction design.

FIG. 8a is a complete device design for the 5-junction solar cell.

FIG. 8b is a graph illustrating the band edge energy positions of CdZnSeTe, AlGaAsSb, and GaInAsSb alloys as functions of their alloy compositions.

FIG. 9 is a graph illustrating the bandgap versus lattice constant for various II/VI and III/V alloys.

FIG. 10 is a layer structure of the proposed lattice-matched 6-junction solar cell design.

FIG. 11 is a graph illustrating the optimal bandgap energies and theoretical conversion efficiency limits calculated using Henry's model for the cells under different normalized photon fluxes near 1 sun condition.

FIG. 12 is a reversed 5-junction PV cell design integrated with an InAsSb sacrificial layer for substrate removal.

FIG. 13a illustrates an as grown wafer with a tandem cell, an InAsSb etching stop layer, and a GaSb substrate.

FIG. 13b illustrates a wafer bonded flip-down to a carrier substrate using photoresist.

FIG. 13c illustrates the GaSb substrate removal etch.

FIG. 13d illustrates the selective etching of the InAsSb etch-stop layer to expose the tandem cell.

FIG. 13e illustrates Au ohmic contact/reflector layer deposition.

FIG. 13f illustrates the release of the tandem cell layer, its bonding to another carrier substrate, deposition of a top metal contact, and coating of the top surface with an anti-reflection layer to finish the device.

### DETAILED DESCRIPTION OF THE INVENTION

It is the object of the present invention to provide for at least one or more of (a) the use of lattice-matched materials may eliminate misfit dislocations that reduce material quality and ultimately conversion efficiency; (b) the use of direct bandgap materials to maximize the absorption and to minimize the thickness of the junction region to minimize series resistance, material usage and growth time; (c) spontaneous emission coupling between adjacent junctions made of direct bandgap semiconductors needs to be taken into account for the optimal design of the bandgap energy and thickness of each multi junction building block and may aid in optimizing the overall conversion efficiency of the whole device; (d) minimization of the series resistance of the contacts, the tunnel junctions, contact layers, and the substrate; and/or (e) decrease the inherent efficiency reduction from the loss of solar radiation below the lowest bandgap energy of present devices; for example, the efficiency reduction is 11% for the case of Ge-based devices having a bandgap of 0.7 eV.

To address these challenges, the instant invention provides multi junction solar cells with one or more of (a) lattice-matched direct-bandgap materials for all the junctions; (b) a design that takes into account spontaneous emission coupling between junctions; (c) a large number of junctions (>3) to reduce the total current; and/or (d) free-standing films (i.e., with the substrate removed) to minimize series resistance and below bandgap IR absorption.

In particular, the instant invention utilizes lattice-matched or pseudomorphically strained II/VI and III/V compound semiconductor material systems for multi junction solar cells that can be grown on III-V or II-VI substrates.

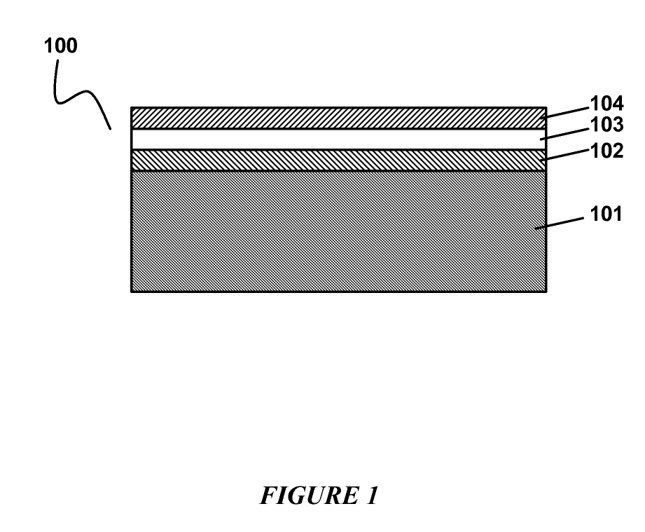

FIG. 1 illustrates an embodiment of the first aspect of the invention, wherein a semiconductor device (100) is provided comprising a substrate (101) and at least three multi junction building blocks (102, 103, 104) formed over the substrate (101). The substrate can be an III-V substrate or an II-VI substrate. When the substrate is an III-V substrate, the III-V substrate can comprise, for example, GaSb, InAs, or InP. When the substrate is an II-VI substrate, the II-VI substrate can comprise, for example, CdSe, CdTe, or ZnTe. Each of the multi junction building blocks (102, 103, 104) independently comprises a p-n junction comprising at least two layers of an III-V or II-VI alloy where one layer is n-doped and the other is p-doped.

Each multi junction building block can optionally comprise other additional layers that are either doped at different levels or have different alloy compositions or even different semiconductor materials, where the layers are made of III-V alloys or II-VI alloys, provided at least one multi junction building block comprises an II-VI alloy layer.

In certain embodiments, the multi junction building blocks are lattice matched or pseudomorphically strained to the substrate. In certain particular embodiments, the multi junction building blocks are lattice matched to the substrate.

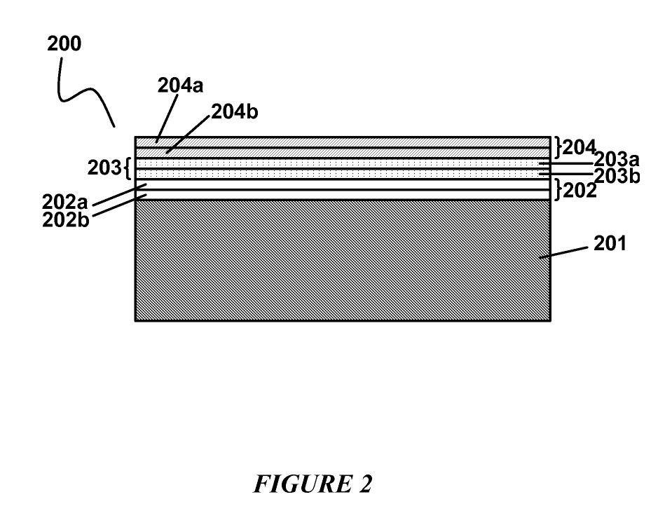

More specifically, referring to FIG. 2, in the semiconductor structure of the first aspect (e.g., FIG. 1), the structure (200) comprises a substrate (201) and at least three multi junction building blocks (202, 203, 204) formed over the substrate (201), wherein each multi junction building block comprises a p-n junction comprising having at least two alloy layers (202a, 202b; 203a, 203b, and 204a, 204b, respectively), where the alloy layers independently comprise a III-V alloy layer or a II-VI alloy, wherein one alloy layer is p-doped and the other alloy layer is n-doped, provided at least one multi junction building block comprises a II-VI alloy layers. Each alloy layer can be doped with a dopant as is familiar to those skilled in the art. For example, Table 1 lists n- and p-doped materials which can be used according to the invention, their respective dopants, and maximum doping concentrations [n (cm⁻³) or p (cm³)] of the dopant therein.

TABLE 1

| | n- | | p- | |
|---|---|---|---|---|
| Materials | Dopants | n (cm⁻³) | Dopants | p (cm⁻³) |
| n-ZnSe | I | >10¹⁸ | N | 4 × 10¹⁷ |
| n-CdSe | Cl | >10¹⁹ | N | 10¹⁷ |
| n-CdTe | I | 7 × 10¹⁸ | N | 2 × 10¹⁷ |
| n-ZnTe | Al, Cl | <4 × 10¹⁸ | P, N | 3 × 10¹⁹ |
| n-MgSeTe | Cl | ~10¹⁹ | N | 7 × 10¹⁷ |
| n-AlGaAsSb | Te | 3 × 10¹⁸ | Be, C | 1 × 10¹⁹ |
| n-GaSb | Te | 7 × 10¹⁸ | Be, C | 1 × 10¹⁹ |

In certain other embodiments, the invention provides the structure according to first aspect (e.g., FIG. 1), wherein each multi junction building block (102, 103, 104) further comprises a third layer contacting the p-n junction. In one embodiment, the third layer comprises the same or different alloy as the p-n junction and is p⁺, P-, n⁺, or N-doped. Particularly, the invention provides the structure wherein each multi-junction building block comprises three layers of the form p⁺pn, pnn⁺, Ppn, or pnN. In one example, each multi junction building block comprises three layers of the form p⁺pn.

In certain other embodiments, the invention provides the structure according to first aspect (e.g., FIG. 1), wherein each multi junction building block (102, 103, 104) further comprises a third and a fourth layer. In one embodiment, the third layer comprises the same or different alloy as the p-n junction and is P- or p⁺-doped; and the fourth layer comprises the same or different alloy as the p-n junction and is N- or n⁺ doped. Particularly, the invention provides the structure wherein each multi-junction building block comprises four layers of the form PpnN, p⁺pnN, p⁺pnn⁺, or Ppnn⁺.

When any layer is an III-V alloy layer, it can comprise, independently, a binary, ternary, quaternary or higher (InGaAl)(AsSbP) alloy. In certain embodiments, each III-V alloy layer independently comprises GaSb, InAsSb, GaInAsSb, or AlGaAsSb. When any layer is an II-VI alloy layer, it can comprise, independently, a binary, ternary, or quaternary (ZnCdHgBeMg)(SeTe) alloy. In certain embodiments, each II-VI alloy layer independently comprises ZnTe, CdSeTe, MgSeTe, ZnCdSeTe, or CdHgSeTe. Each layer in a multi junction building block can be chosen such that bandgap energy (E_{g}) of each of the multi junction building blocks is a value between 0.35-3.00 eV. In certain embodiments, the bandgap of each multi junction building block is 0.35-0.65 eV, 0.50-1.00 eV, 0.60-1.00 eV, 0.80-1.20 eV, 0.90-1.50 eV, 1.10-1.50 eV, 1.25-1.75 eV, 1.45-1.85 eV, 1.75-2.50 eV, 2.00-2.50 eV, and/or 2.50-3.00 eV.

In another embodiment, the invention provides the structure according to any of the preceding embodiments, wherein the semiconductor structure comprises four multi junction building blocks formed over the substrate. For example, the semiconductor structure can comprise four building blocks, wherein a first building block comprises GaSb (e.g., having an E_{g} about 0.50 to 0.90 eV, or about 0.60 to 0.80 eV), a second building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 to 1.40 eV), a third building block comprises ZnₓCd₁₋ₓSe_{y}Te_{1-y} wherein x is about 0 to 0.59 and y is about 0.90 to 0.38 (e.g., having an E_{g} about 1.50 to 1.90 eV or about 1.60 eV to 1.80 eV), and a fourth building block comprises ZnTe (e.g., having an E_{g} about 2.00 to 2.50 eV or about 2.15 to 2.35 eV). In such embodiments, the first through fourth building blocks can be formed sequentially over one another, i.e., the first building block is formed over the substrate, the second building block is formed over the first building block, and so on.

In yet another embodiment, the invention provides the structure according to any of the preceding embodiments, wherein the semiconductor structure comprises five multi junction building blocks formed over the substrate. For example, the semiconductor structure can comprise five building blocks, wherein a first building block comprises GaₓIn₁₋ₓAs_{y}Sb_{1-y} wherein x is about 0.02 to 0.97 and y is about 0.90 to 0.03 (e.g., having an E_{g} about 0.30 to 0.70 eV, or about 0.40 to 0.60 eV), a second building block comprises GaSb (e.g., having an E_{g} about 0.50 to 0.90 eV or about 0.60 to 0.80 eV), a third building block comprises AlₓGa₁₋ₓAs_{y}Sb_{1-y} wherein x is about 0.17 to 0.52 and y is about 0.01 to 0.04 (e.g., having an E_{g} about 1.00 to 1.40 eV or about 1.10 eV to 1.30 eV), a fourth building block comprises CdSeₓTe₁₋ₓ wherein x is about 0.67 to 0.90 (e.g., having an E_{g} about 1.30 to 1.70 eV or about 1.40 eV to 1.60 eV), and a fifth building block comprises ZnTe (e.g., having an E_{g} about 2.00 to 2.50 eV or about 2.15 to 2.35 eV). In such embodiments, the first through fifth building blocks can be formed sequentially over one another, i.e., the first building block is formed over the substrate, the second building block is formed over the first building block, and so on.

In yet another embodiment, the invention provides the structure according to any of the preceding embodiments, wherein the semiconductor structure comprises six multi junction building blocks formed over the substrate. For example, the semiconductor structure can comprise six building blocks, wherein a first building block comprises GaₓIn₁₋ₓAs_{y}Sb_{1-y}, wherein x is about 0.02 to 0.97 and y is about 0.90 to 0.03 (e.g., having an E_{g} about 0.30 to 0.70 eV, or about 0.40 to 0.60 eV), a second building block comprises AlₓGa₁₋ₓAs_{y}Sb_{1-y} wherein x is about 0 to 0.18 and y is about 0 to 0.01 (e.g., having an E_{g} about 0.60 to 1.00 eV or about 0.70 to 0.90 eV), a third building block comprises AlₓGa₁₋ₓAs_{y}Sb_{1-y} wherein x is about 0.04 to 0.32 and y is about 0 to 0.03 (e.g., having an E_{g} about 0.80 to 1.20 eV or about 0.90 eV to 1.10 eV), a fourth building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 eV to 1.40 eV), a fifth building block comprises ZnₓCd₁₋ₓSe_{y}Te_{1-y} wherein x is about 0 to 0.52 and y is about 0.90 to 0.44 (e.g., having an E_{g} about 1.45 to 1.85 eV or about 1.55 to 1.75 eV), and a sixth building block comprises ZnTe (e.g., having an E_{g} about 2.00 to 2.50 eV or about 2.15 to 2.35 eV). In such embodiments, the first through sixth building blocks can be formed sequentially over one another, i.e., the first building block is formed over the substrate, the second building block is formed over the first building block, and so on.

In certain of the preceding embodiments, each of the layers has a bandgap greater than the bandgap of the multi junction building block it is formed over. In other certain of the preceding embodiments, each of the layers has a bandgap less than the bandgap of the multi junction building block it is formed over. In other certain of the preceding embodiments, each of the multi junction building blocks is lattice matched or pseudomorphically strained to the substrate. In other certain of the preceding embodiments, each of the multi junction building blocks are lattice matched to the substrate.

The semiconductor structures of first aspect (e.g., FIGS. 1 and 2) and any embodiment thereof, can further comprise at least one tunnel junction between any two of the multi junction building blocks. In other embodiments, the structure can further comprise a tunnel junction between each of the multi junction building blocks. In yet other embodiments, the structure can further comprise at least one tunnel junction which is formed naturally between any two multi junction building blocks.

The semiconductor structures of first aspect can also further comprise, as necessary, a buffer layer between the substrate and the first multi junction building block formed over the substrate. Such buffer layers can comprise an appropriate material or multiple layers of materials as known to those skilled in the art, for example, to promote growth of a multi junction building block over the substrate.

Further additional components, which are familiar to those skilled in the art, which can be included in the semiconductor structures of the first aspect include, n- and/or p-contact layers (e.g., ohmic contacts). Such contact layers can be in contact with the substrate or the upper-most layer of the multi junction building blocks formed over the substrate. In certain embodiments, the ohmic contacts can comprise a conductive metal layer; examples of conductive metals include, but are not limited to, gold, silver, platinum, palladium, nickel, calcium, magnesium, tungsten, indium, indium/mercury, tin, gold/tin, mixtures, and multilayers thereof. Further examples of such contacts which can be utilized with various multi-junction building blocks and/or substrates are listed in Table 2.

TABLE 2
Ohmic Contacts

| | | | |
|---|---|---|---|
| ZnTe, n-contact | W, In, or In/Hg | ZnTe, p-contact | Au, Pt, Au/Pt/Pd, |
| | | | Au/Pt/Ti/Ni |
| GaSb, n-contact | AuSn/Ti/Pt/Au | GaSb, p-contact | Ti/Pt/Au or Au |

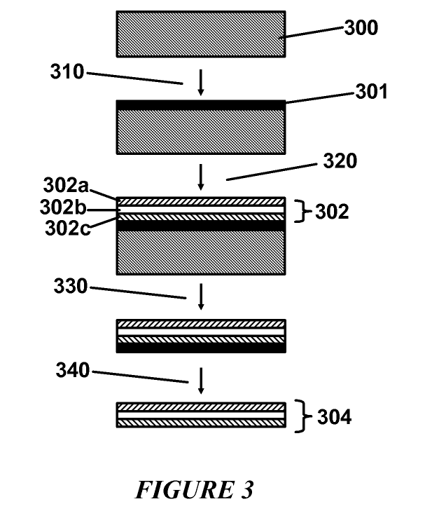

In a second aspect, and as illustrated in FIG. 3, the invention provides a method for preparing a semiconductor structure (304) comprising, preparing (310) a sacrificial layer or an etch-stop ternary III-V alloy layer (301) over a III-V substrate (300); preparing (320) a semiconductor structure (302) comprising at least three multi junction building blocks (302a, 302b, 302c) formed over the sacrificial or etch-stop ternary III-V alloy layer (301), wherein each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers; removing the substrate (330); and removing the sacrificial alloy layer (340).

The III-V substrate (300) can comprise, for example, GaSb, InAs, or InP. In certain embodiments, the III-V substrate (300) comprises GaSb. The sacrificial ternary III-V layer (301) can comprise, for example, InAsSb. The semiconductor structure (302) comprising at least three multi junction building blocks (302a, 302b, 302c) can be prepared, for example via liquid phase epitaxy (LPE), molecular beam epitaxy (MBE) or metal organic chemical vapor deposition (MOCVD).

In certain embodiments of the second aspect, after preparing the semiconductor structure, the III-V substrate is removed via chemical etching. For example, the chemical etching can comprise jet-spin etching according to conditions known to those skilled in the art. In a particular example, the chemical etching can comprise jet-spin etching by contacting the substrate with H₂O₂:H₂O:NaK. In other embodiments, the chemical etching can comprise contacting the substrate with CrO₃, HF, and H₂O.

In certain other embodiments of the second aspect, after removal of the substrate via etching the substrate, the etch-stop layer can be removed via chemical etching. For example, the chemical etching can comprise contacting the etch stop layer with citric acid and H₂O₂.

In certain other embodiments of the second aspect, the substrate can be removed by etching or dissolution of the sacrificial layer as are familiar to those skilled in the art.

In any of the preceding embodiments of the second aspect, each multi junction building block can be one or more of, (a) lattice matched to the substrate; and/or (b) comprise a p-n junction comprising two layers; (c) comprise a p-n junction and a third layer comprising the same or different alloy as the p-n junction and the third layer is p⁺, P-, n⁺, or N-doped (e.g., of the form p⁺pn, pnn⁺, Ppn, or pnN); or (d) comprise a p-n junction and a third and a fourth layer wherein the third layer comprises the same or different alloy as the p-n junction and is P- or p⁺-doped; and the fourth layer comprises the same or different alloy as the p-n junction and is N- or n⁺ doped (e.g., of the form PpnN, p⁺pnN, p⁺pnn⁺, or Ppnn⁺).

When a multi junction building block comprises III-V alloy layers, the multi-junction building block can independently comprise a binary, ternary, quaternary, or higher (InGaAl)(AsSbP) alloy. For example, the III-V multi junction building block can independently comprise GaSb, InAsSb, GaInAsSb, or AlGaAsSb. When a multi-junction building block comprises II-VI alloy layers, the multi junction building block can independently comprise a binary, ternary, or quaternary (ZnCdHgBeMg)(SeTe) alloy. For example, the II-VI multi junction building block can independently comprise ZnTe, CdSeTe, MgSeTe, ZnCdSeTe, or CdHgSeTe. Each multi junction building block can be chosen such that bandgap energy (E_{g}) of each of the multi-junction building block is a value between 0.35-3.00 eV. In certain embodiments, the bandgap of each multi junction building block is 0.35-0.65 eV, 0.50-1.00 eV, 0.60-1.00 eV, 0.80-1.20 eV, 0.90-1.50 eV, 1.10-1.50 eV, 1.25-1.75 eV, 1.45-1.85 eV, 1.75-2.50 eV, 2.00-2.50 eV, and/or 2.50-3.00 eV.

Further, in any of the preceding embodiments of the second aspect, the semiconductor structure can comprise four, five, or six multi junction building blocks formed over the substrate.

In certain embodiments of the second aspect, the semiconductor structure according to any of the preceding embodiments can comprise four multi junction building blocks formed over the substrate. For example, the semiconductor structure can comprise four building blocks, wherein a first building block comprises GaSb (e.g., having an E_{g} about 0.50 to 0.90 eV, or about 0.60 to 0.80 eV), a second building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 to 1.40 eV), a third building block comprises ZnₓCd₁₋ₓSe_{y}Te_{1-y} wherein x is about 0 to 0.59 and y is about 0.90 to 0.38 (e.g., having an E_{g} about 1.50 to 1.90 eV or about 1.60 eV to 1.80 eV), and a fourth building block comprises ZnTe (e.g., having an E_{g} about 2.00 to 2.50 eV or about 2.15 to 2.35 eV). In such embodiments, the first through fourth building blocks can be formed sequentially over one another, i.e., the first building block is formed over the substrate, the second building block is formed of the first building block, and so on.

In certain other embodiments of the second aspect, the semiconductor structure according to any of the preceding embodiments can comprise five multi-junction building blocks formed over the substrate. For example, the semiconductor structure can comprise five building blocks, wherein a first building block comprises GaₓIn₁₋ₓAs_{y}Sb_{1-y} wherein x is about 0.02 to 0.97 and y is about 0.90 to 0.03 (e.g., having an E_{g} about 0.30 to 0.70 eV, or about 0.40 to 0.60 eV), a second building block comprises GaSb (e.g., having an E_{g} about 0.50 to 0.90 eV or about 0.60 to 0.80 eV), a third building block comprises AlₓGa₁₋ₓAs_{y}Sb_{1-y} wherein x is about 0.17 to 0.52 and y is about 0.01 to 0.04 (e.g., having an E_{g} about 1.00 to 1.40 eV or about 1.10 eV to 1.30 eV), a fourth building block comprises CdSeₓTe₁₋ₓ wherein x is about 0.67 to 0.90 (e.g., having an E_{g} about 1.30 to 1.70 eV or about 1.40 eV to 1.60 eV), and a fifth building block comprises ZnTe (e.g., having an E_{g} about 2.00 to 2.50 eV or about 2.15 to 2.35 eV). In such embodiments, the first through fifth building blocks can be formed sequentially over one another, i.e., the first building block is formed over the substrate, the second building block is formed of the first building block, and so on.

In yet other embodiments of the second aspect, the semiconductor structure according to any of the preceding embodiments can comprise six multi junction building blocks formed over the substrate. For example, the semiconductor structure can comprise six building blocks, wherein a first building block comprises GaₓIn₁₋ₓAs_{y}Sb_{1-y}, wherein x is about 0.02 to 0.97 and y is about 0.90 to 0.03 (e.g., having an E_{g} about 0.30 to 0.70 eV, or about 0.40 to 0.60 eV), a second building block comprises AlₓGa₁₋ₓAs_{y}Sb_{1-y} wherein x is about 0 to 0.18 and y is about 0 to 0.01 (e.g., having an E_{g} about 0.60 to 1.00 eV or about 0.70 to 0.90 eV), a third building block comprises AlₓGa₁₋ₓAs_{y}Sb_{1-y} wherein x is about 0.04 to 0.32 and y is about 0 to 0.03 (e.g., having an E_{g} about 0.80 to 1.20 eV or about 0.90 eV to 1.10 eV), a fourth building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 eV to 1.40 eV), a fifth building block comprises ZnₓCd₁₋ₓSe_{y}Te_{1-y} wherein x is about 0 to 0.52 and y is about 0.90 to 0.44 (e.g., having an E_{g} about 1.45 to 1.85 eV or about 1.55 to 1.75 eV), and a sixth building block comprises ZnTe (e.g., having an E_{g} about 2.00 to 2.50 eV or about 2.15 to 2.35 eV). In such embodiments, the first through sixth building blocks can be formed sequentially over one another, i.e., the first building block is formed over the substrate, the second building block is formed of the first building block, and so on.

In certain of the preceding embodiments of the second aspect, each of multi-junction building blocks has a bandgap greater than the layer it is formed over. In other certain of the preceding embodiments, each of multi junction building blocks has a bandgap less than the layer it is formed over.

In other certain of the preceding embodiments of the second aspect, each of the multi junction building blocks is lattice matched or pseudomorphically strained to the substrate. In other certain of the preceding embodiments of the second aspect, each of the multi junction building blocks are lattice matched to the substrate.

The semiconductor structures prepared according the second aspect, and any embodiment thereof, can further comprise at least one tunnel junction between any two of the multi junction building blocks. In other embodiments, the structure can further comprise a tunnel junction between each of the multi junction building blocks. In yet other embodiments, the structure can further comprise at least one tunnel junction which is formed naturally between any two multi junction building blocks. The structure can also further comprise, as necessary, a buffer layer between the substrate and the first multi junction building block formed over the substrate. Such buffer layers can comprise an appropriate material or multiple layers of different materials as known to those skilled in the art, for example, to promote growth of a multi junction building block over the substrate.

In a third aspect, the invention provides a semiconductor structure prepared according to any embodiment of the second aspect.

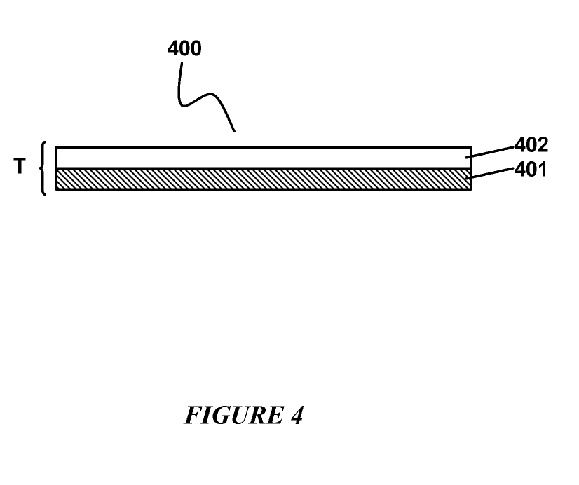

In a fourth aspect, the invention provides a structure as illustrated in FIG. 4, where the semiconductor structure (400) comprises at least two multi junction building blocks (401, 402), wherein each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers. In certain embodiments, the semiconductor structure can comprise three, four, five, or six multi junction building blocks.

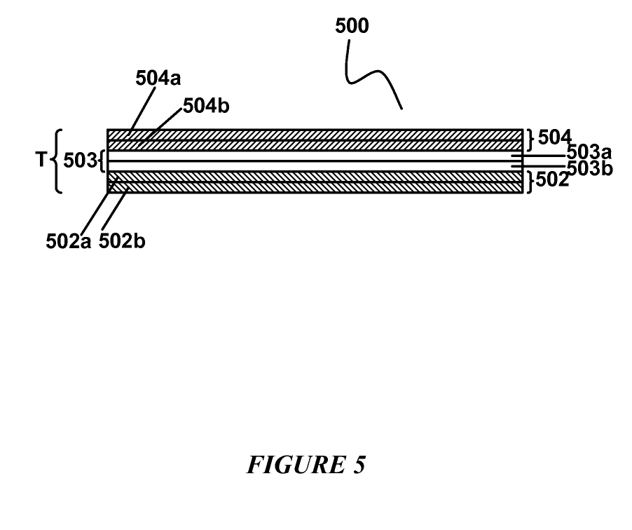

Referring to FIG. 5, in certain embodiments of the semiconductor structure of the fourth aspect, the structure (500) can comprise at least three multi junction building blocks (502, 503, 504), wherein each multi junction building block comprises a p-n junction comprising at least two layers (502a, 502b; 503a, 503b, and 504a, 504b, respectively). As is familiar to one skilled in the art, within each multi-junction building block, one of the layers therein is p-doped and the one of the other layers is n-doped. Each layer can be doped with a dopant as is familiar to those skilled in the art as discussed previously (supra).

In certain other embodiments of the fourth aspect, the invention provides the structure according to the fourth aspect, wherein each multi junction building block (502, 503, 504) comprises a p-n junction and a third layer. Particularly, the third layer can comprise the same or different alloy as the p-n junction and the third layer is p⁺, P-, n⁺, or N-doped (e.g., of the form, p⁺pn, pnn⁺, Ppn, or pnN). In one example, each multi junction building block comprises three layers of the form p⁺pn.

In certain other embodiments of the fourth aspect, the invention provides the structure according to the fourth aspect, wherein each multi junction building block (502, 503, 504) comprises a p-n junction and a third layer and a fourth layer. Particularly, the third layer can comprise the same or different alloy as the p-n junction and is P- or p⁺-doped; and the fourth layer can comprise the same or different alloy as the p-n junction and is N- or n⁺ doped (e.g., of the form PpnN, p⁺pnN, p⁺pnn⁺, or Ppnn⁺).

When any multi junction building block of the semiconductor structure of the fourth aspect comprises III-V alloy layers, it can comprise, independently, binary, ternary, quaternary, or higher (InGaAl)(AsSbP) alloy layers. In certain embodiments, each III-V alloy layer independently comprises GaSb, InAsSb, GaInAsSb, or AlGaAsSb. When any multi junction building block comprises II-VI alloy layers, it can comprise, independently, binary, ternary, or quaternary (ZnCdHgBeMg)(SeTe) alloy layers. In certain embodiments, each II-VI alloy layer independently comprises ZnTe, CdSeTe, MgSeTe, ZnCdSeTe, or CdHgSeTe. The material can be chosen such that bandgap energy (E_{g}) of the p-n junction in each of the multi junction building block is a value between 0.35-3.00 eV. In certain embodiments, the bandgap of the p-n junction in each multi junction building block is 0.35-0.65 eV, 0.50-1.00 eV, 0.60-1.00 eV, 0.80-1.20 eV, 0.90-1.50 eV, 1.10-1.50 eV, 1.25-1.75 eV, 1.45-1.85 eV, 1.75-2.50 eV, 2.00-2.50 eV, and/or 2.50-3.00 eV.

In certain of the preceding embodiments of the fourth aspect, the p-n junction in each of multi junction building blocks has a bandgap greater than that of the multi-junction building block it is formed over. In other certain of the preceding embodiments, each of multi junction building blocks has bandgap less than that of the multi junction building block it is formed over.

In other certain of the preceding embodiments of the fourth aspect, each of the multi junction building blocks is lattice matched or pseudomorphically strained to the substrate. In other certain of the preceding embodiments of the second aspect, each of the multi junction building blocks are lattice matched to the substrate.

The semiconductor structures of the fourth aspect, (e.g., FIGS. 4 and 5), and any embodiment thereof, can further comprise at least one tunnel junction between any two of the multi junction building blocks. In other embodiments, the structure can further comprise a tunnel junction between each of the multi junction building blocks. In yet other embodiments, the structure can further comprise at least one tunnel junction which is formed naturally between any two multi junction building blocks. The structure can also further comprise, as necessary, a buffer layer between the substrate and the first multi junction building block formed over the substrate. Such buffer layers can comprise an appropriate material or multiple layers of different materials as known to those skilled in the art, for example, to promote growth of a multi junction building block over the substrate.

Further additional components, which are familiar to those skilled in the art, which can be included in the semiconductor structures of the first aspect include, n- and/or p-contact layers (e.g., ohmic contacts). Such contact layers can be in contact with the substrate or the upper-most of the multi junction building blocks formed over the substrate. In certain embodiments, the ohmic contacts can comprise a conductive metal layer; examples of conductive metals include, but are not limited to, gold, silver, platinum, palladium, nickel, calcium, magnesium, tungsten, indium, indium/mercury, tin, gold/tin, mixtures, and multilayers thereof. Further examples of such contacts which can be utilized with various multi junction building blocks and/or substrates are listed in Table 2.

In any embodiments of the fourth aspect, the thickness of the semiconductor structure (e.g., (T) in FIGS. 4 and 5) can be less than 10.0 μm, 7.5 μm, 5.0 μm, 4.5 μm, 4.0 μm, 3.5 μm, 3.0 μm, 2.5 μm, 2.0 μm, 1.5 μm, 1.0 μm, or 0.5 μm. In certain other embodiments, the thickness of the semiconductor structure can be 0.5 μm-10 μm, 1.0 μm-10 μm, 1.5 μm-10 μm, 2.0 μm-10 μm, 2.5 μm-10 μm, 0.5 μm-5.0 μm, 1.0 μm-5.0 μm, 1.5 μm-5.0 μm, or 2.0 μm-5.0 μm.

In a fifth aspect the invention provides methods for preparing a semiconductor structure comprising, comprising forming at least three multi junction building blocks over a substrate, wherein the substrate is a III-V substrate or a II-VI substrate; and each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers.

In the fifth aspect, the III-V substrate can comprise, for example, GaSb, InAs, or InP. In certain embodiments, the III-V substrate comprises GaSb.

The at least three multi junction building blocks can be prepared, for example via liquid phase epitaxy (LPE), molecular beam epitaxy (MBE) or metal organic chemical vapor deposition (MOCVD).

In any of the preceding embodiments of the fifth aspect, each multi junction building block can be one or more of, (a) lattice matched to the substrate; and/or (b) comprise a p-n junction comprising two layers; (c) comprise a p-n junction and a third layer comprising the same or different alloy as the p-n junction and the third layer is p⁺, P-, n⁺, or N-doped (e.g., of the form p⁺pn, pnn⁺, Ppn, or pnN); or (d) comprise a p-n junction and a third and a fourth layer wherein the third layer comprises the same or different alloy as the p-n junction and is P- or p⁺-doped; and the fourth layer comprises the same or different alloy as the p-n junction and is N- or n⁺ doped (e.g., of the form PpnN, p⁺pnN, p⁺pnn⁺, or Ppnn⁺).

When a multi junction building block comprises III-V alloy layers, the multi-junction building block can independently comprise a binary, ternary, quaternary, or higher (InGaAl)(AsSbP) alloy. For example, the III-V multi junction building block can independently comprise GaSb, InAsSb, GaInAsSb, or AlGaAsSb. When a multi-junction building block comprises II-VI alloy layers, the multi junction building block can independently comprise a binary, ternary, or quaternary (ZnCdHgBeMg)(SeTe) alloy. For example, the II-VI multi junction building block can independently comprise ZnTe, CdSeTe, MgSeTe, ZnCdSeTe, or CdHgSeTe. Each multi junction building block can be chosen such that bandgap energy (E_{g}) of each of the multi-junction building block is a value between 0.35-3.00 eV. In certain embodiments, the bandgap of each multi junction building block is 0.35-0.65 eV, 0.50-1.00 eV, 0.60-1.00 eV, 0.80-1.20 eV, 0.90-1.50 eV, 1.10-1.50 eV, 1.25-1.75 eV, 1.45-1.85 eV, 1.75-2.50 eV, 2.00-2.50 eV, and/or 2.50-3.00 eV.

Further, in any of the preceding embodiments of the fifth aspect, the semiconductor structure can comprise four, five, or six multi junction building blocks formed over the substrate.

In certain embodiments of the fifth aspect, the semiconductor structure according to any of the preceding embodiments can comprise four multi junction building blocks formed over the substrate. For example, the semiconductor structure can comprise four building blocks, wherein a first building block comprises GaSb (e.g., having an E_{g} about 0.50 to 0.90 eV, or about 0.60 to 0.80 eV), a second building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 to 1.40 eV), a third building block comprises ZnₓCd₁₋ₓSe_{y}Te_{1-y} wherein x is about 0 to 0.59 and y is about 0.90 to 0.38 (e.g., having an E_{g} about 1.50 to 1.90 eV or about 1.60 eV to 1.80 eV), and a fourth building block comprises ZnTe (e.g., having an E_{g} about 2.00 to 2.50 eV or about 2.15 to 2.35 eV). In such embodiments, the first through fourth building blocks can be formed sequentially over one another, i.e., the first building block is formed over the substrate, the second building block is formed of the first building block, and so on.

In certain other embodiments of the fifth aspect, the semiconductor structure according to any of the preceding embodiments can comprise five multi junction building blocks formed over the substrate. For example, the semiconductor structure can comprise five building blocks, wherein a first building block comprises GaₓIn₁₋ₓAs_{y}Sb_{1-y} wherein x is about 0.02 to 0.97 and y is about 0.90 to 0.03 (e.g., having an E_{g} about 0.30 to 0.70 eV, or about 0.40 to 0.60 eV), a second building block comprises GaSb (e.g., having an E_{g} about 0.50 to 0.90 eV or about 0.60 to 0.80 eV), a third building block comprises AlₓGa₁₋ₓAs_{y}Sb_{1-y} wherein x is about 0.17 to 0.52 and y is about 0.01 to 0.04 (e.g., having an E_{g} about 1.00 to 1.40 eV or about 1.10 eV to 1.30 eV), a fourth building block comprises CdSeₓTe₁₋ₓ wherein x is about 0.67 to 0.90 (e.g., having an E_{g} about 1.30 to 1.70 eV or about 1.40 eV to 1.60 eV), and a fifth building block comprises ZnTe (e.g., having an E_{g} about 2.00 to 2.50 eV or about 2.15 to 2.35 eV). In such embodiments, the first through fifth building blocks can be formed sequentially over one another, i.e., the first building block is formed over the substrate, the second building block is formed of the first building block, and so on.

In yet other embodiments of the fifth aspect, the semiconductor structure according to any of the preceding embodiments can comprise six multi junction building blocks formed over the substrate. For example, the semiconductor structure can comprise six building blocks, wherein a first building block comprises GaₓIn₁₋ₓAs_{y}Sb_{1-y}, wherein x is about 0.02 to 0.97 and y is about 0.90 to 0.03 (e.g., having an E_{g} about 0.30 to 0.70 eV, or about 0.40 to 0.60 eV), a second building block comprises AlₓGa₁₋ₓAs_{y}Sb_{1-y} wherein x is about 0 to 0.18 and y is about 0 to 0.01 (e.g., having an E_{g} about 0.60 to 1.00 eV or about 0.70 to 0.90 eV), a third building block comprises AlₓGa₁₋ₓAs_{y}Sb_{1-y} wherein x is about 0.04 to 0.32 and y is about 0 to 0.03 (e.g., having an E_{g} about 0.80 to 1.20 eV or about 0.90 eV to 1.10 eV), a fourth building block comprises AlₓGa₁₋ₓAs_{y}Sb_{1-y} wherein x is about 0.24 to 0.66 and y is about 0.02 to 0.05 (e.g., having an E_{g} about 1.10 to 1.50 eV or about 1.20 eV to 1.40 eV), a fifth building block comprises CdₓZn₁₋ₓSe_{y}Te_{1-y} wherein x is about 0 to 0.52 and y is about 0.90 to 0.44 (e.g., having an E_{g} about 1.45 to 1.85 eV or about 1.55 to 1.75 eV), and a sixth building block comprises ZnTe (e.g., having an E_{g} about 2.00 to 2.50 eV or about 2.15 to 2.35 eV). In such embodiments, the first through sixth building blocks can be formed sequentially over one another, i.e., the first building block is formed over the substrate, the second building block is formed of the first building block, and so on.

In certain of the preceding embodiments of the fifth aspect, each of multi-junction building blocks has a bandgap greater than the layer it is formed over. In other certain of the preceding embodiments, each of multi junction building blocks has a bandgap less than the layer it is formed over.

In other certain of the preceding embodiments of the fifth aspect, each of the multi junction building blocks is lattice matched or pseudomorphically strained to the substrate. In other certain of the preceding embodiments of the fifth aspect, each of the multi junction building blocks are lattice matched to the substrate.

The semiconductor structures prepared according the fifth aspect, and any embodiment thereof, can further comprise at least one tunnel junction between any two of the multi junction building blocks. In other embodiments, the structure can further comprise a tunnel junction between each of the multi junction building blocks. In yet other embodiments, the structure can further comprise at least one tunnel junction which is formed naturally between any two multi junction building blocks. The structure can also further comprise, as necessary, a buffer layer between the substrate and the first multi junction building block formed over the substrate. Such buffer layers can comprise an appropriate material or multiple layers of different materials as known to those skilled in the art, for example, to promote growth of a multi junction building block over the substrate.

### DEFINITIONS

Herein, a notation is used to refer to alloys having the form of two sets of elements each within its own set of parenthesis; for example, (ABCD)(EFGH). This notation means that the alloy comprised at least one element selected from A, B, C, and D, and at least one element selected from E, F, G, and H. When this notation is used in combination with the modifiers such as “binary”, “ternary”, “quaternary”, “quinary”, or “senary”, among others, it means that the alloy contains a total of 2, 3, 4, 5, or even 6 elements, respectively, provided that at least one element selected from A, B, C, and D, and at least one element selected from E, F, G, and H. For example, a ternary (InGaAl)(AsSb) alloy includes both InAsSb and GaAlSb, among other combinations.

The term “II-VI alloy” as used herein means an alloy where the constituent elements are selected from Groups IIA, IIB, and VIA, of the periodic table, wherein at least one constituent element is selected from Groups IIA and/or IIB of the periodic table and at least one constituent element is selected from Group VIA of the periodic table. Examples of II-VI alloys include, but are not limited to (a) binary alloys such as, but not limited to, Cadmium selenide (CdSe), Cadmium sulfide (CdS), Cadmium telluride (CdTe), Zinc oxide (ZnO), Zinc selenide (ZnSe), Zinc sulfide (ZnS), and Zinc telluride (ZnTe); (b) ternary alloy such as, but not limited to, Cadmium zinc telluride (CdZnTe, CZT), Mercury cadmium telluride (HgCdTe), Mercury zinc telluride (HgZnTe), and Mercury zinc selenide (HgZnSe); and (c) quaternary alloys such as, but not limited to, Cadmium mercury selenide telluride (CdHgSeTe) and Cadmium zinc selenide telluride (CdZnSeTe).

The term “III-V alloy” as used herein means an alloy where the constituent elements are selected from Groups IIIA and VA of the periodic table, wherein at least one constituent element is selected from Group IIIA of the periodic table and at least one constituent element is selected from Group VA of the periodic table. Examples of III-V alloys include, but are not limited to (a) binary alloys such as, but not limited to, Aluminum antimonide (AlSb), Aluminum arsenide (AlAs), Aluminum nitride (AlN), Aluminum phosphide (AlP), Boron nitride (BN), Boron phosphide (BP), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), and Indium phosphide (InP); (b) ternary alloys, but not limited to, Aluminum gallium arsenide (AlGaAs, AlₓGa₁₋ₓAs), Indium gallium arsenide (InGaAs, InₓGa₁₋ₓAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), and Indium gallium antimonide (InGaSb); (c) quaternary alloys such as, but not limited to, Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), and Indium aluminum arsenide nitride (InAlAsN); and (d) quinary alloys such as, but not limited to, Gallium indium nitride arsenide antimonide (GaInNAsSb). Higher order alloys include, for example, the senary alloy Indium gallium aluminum arsenide antimonide phosphide InGaAlAsSbP.

The term “bandgap” or “E_{g}” as used herein means the energy difference between the highest occupied state of the valence band and the lowest unoccupied state of the conduction band of the material. The bandgap for a multi junction building block, as used herein, refers to the bandgap of the material that form the p-n junction.

The term “lattice matched” as used herein means that the two referenced materials have the same or lattice constants differing by up to +/−0.2%. For example, GaAs and AlAs are lattice matched, having lattice constants differing by ˜0.12%.

The term “pseudomorphically strained” as used herein means that layers made of different materials with a lattice parameter difference up to +/−2% that can be grown on top of other lattice matched or strained layers without generating misfit dislocations. In certain embodiments, the lattice parameters differ by up to +/−1%. In other certain embodiments, the lattice parameters differ by up to +/−0.5%. In further certain embodiments, the lattice parameters differ by up to +/−0.2%.

The term “multi junction building block” as used herein, means a region comprising a p-n junction having at least two layers of similar or dissimilar materials doped n and p type, respectively, where the absorption edge of this p-n junction defines the bandgap of the multi junction building block, as defined herein. However, such multi junction building blocks can comprise multiple layers. For example, a multi junction building block can comprise a p-n junction and a third doped layer to form a Ppn⁺ structure, wherein the P region can comprise material that has the same or larger bandgap than that of the p-n region, or a multi junction building block can comprise a p-n junction and one additional doped layer on each side of the p-n junction to form a PpnN structure, wherein the P and the N regions can comprise materials that have the same or larger bandgap than that of the p-n junction region.

The term “layer” as used herein, means a continuous region of a material (e.g., an alloy) that can be uniformly or non-uniformly doped and that can have a uniform or a non-uniform composition across the region.

The term “pseudomorphically strained” as used herein, means a strained epitaxial material without misfit dislocations.

The term “tunnel junction” as used herein, means a region comprising two heavily doped layers with n and p, respectively. Both of these layers can be of the same materials (homojunction) or different materials (heterojunction).

The term “p-doped” as used herein means atoms have been added to the material (e.g., an alloy) to increase the number of free positive charge carriers.

The term “n-doped” as used herein means atoms have been added to the material (e.g., an alloy) to increase the number of free negative charge carriers.

The term “p⁺-doped” as used herein means atoms have been added to the material (e.g., an alloy) to increase the number of free positive charge carriers such that the material is degenerate, as is known to those skilled in the art.

The term “n⁺-doped” as used herein means atoms have been added to the material (e.g., alloy) to increase the number of free negative charge carriers such that the material is degenerate, as is known to those skilled in the art.

The term “P-doped” as used herein means the material is p-doped, as defined herein, and the bandgap of the material is the same or greater than the p-doped material of a p-n junction.

The term “N-doped” as used herein means the material is n-doped, as defined herein, and the bandgap of the material is the same or greater than the n-doped material of a p-n junction.

### EXAMPLES

### Example 1

### MBE Growth of Materials and Device Structures

The proposed materials and devices are grown using molecular beam epitaxy (MBE) machines. In these examples an MBE machine are used to grow antimonides while a II/VI MBE chamber are used for the growth of, for example, (CdZn)(SeTe).

As discussed above, it is preferable to have high performance tunnel junctions with very small series resistance in multi junction solar cells. MBE techniques offer the capability to grow tunnel junctions as it can do δ-doping, which results in extremely abrupt doping profile with very high concentration. Te and Be are used as n- and p-type dopants for antimonides while Cl and N are used as n- and p-type dopants for II/VI materials. As previous work has shown, these dopants can reach the required doping concentrations for the solar cell junctions and tunnel junctions in the materials of interest.

MBE growth can be monitored using in situ monitoring tools such as Reflection High-Energy Electron Diffraction (RHEED). The epitaxial layers and device structures will be characterized using high-resolution x-ray diffraction, Hall measurements, and room temperature and low temperature photoluminescence (PL) measurements. Analysis of the results of these measurements is used to optimize the growth of various materials and devices. It may be necessary to have both the lattice constant obtained from the x-ray data and the bandgap measured using PL to determine the accurate alloy compositions.

The p-type doping of the selenides, which is notoriously difficult, can be greatly enhanced by using a grading strategy with ZnTe; e.g., one can start with ZnTe and increase the CdSe constituent, and thus maintain the high Fermi level established in ZnTe without affecting the lattice parameter. This process has been spectacularly successful in the development of ZnSe diode blue-green laser. [see, Luo and Furdyna, Semicond. Sci. Technol. 10, 1041 (1995)]

### Example 2

### 4-Junction Solar Cell

A four junction solar cell design for AM0 spectrum consists of two quaternary alloy junctions and two binary junctions, as opposed to four quaternary alloy junctions for an ideal design. Simulation of this design is carried out using the commercial software package Silvaco. Losses due to the Shockley-Read-Hall, radiative, and Auger recombination mechanisms are included. In order to optimize the practical design, where less than ideal bandgap energies are used, the thicknesses of each subcell is selected to attain the largest feasible working voltage for each subcell at the working current of the entire solar cell.

The design parameters and calculated performance for a practical four-junction solar cell (under one sun AM0) are given in Table 3. Top to bottom, the four subcell layers 1-4 are, ZnTe, Zn_{0.27}Cd_{0.73}Se_{0.66}Te_{0.34}, Al_{0.40}Ga_{0.60}As_{0.03}Sb_{0.97}, and GaSb (all lattice matched to GaSb), with optimal subcell thicknesses, d, that are 1.20, 1.20, 1.70, and 1.10 μm, respectively. The short circuit current, I_{SC}, the open circuit voltage, V_{OC}, and the fill factor are given for each subcell illuminated individually. Optimal power conversion for the entire solar cell occurs at a working current of Iₘ=13.29 mA and a working voltage of Vₘ=4.12 V. The input material parameters such as absorption coefficients, effective masses, recombination coefficients, and carrier mobilities are obtained from linearly interpolated published values [see, S. Adachi, Properties of Group-IV, III-V and II-VI Semiconductors, (Wiley, West Sussex, England, 2005); and Handbook of Optical Constants of Solids, edited by E D Palik (Academic Press, New York, 1985)]. The simulations utilize the finite element method along with a two-dimensional drift-diffusion model for carrier transport that takes position-dependent carrier generation and recombination into account.

TABLE 3
Design parameters and predicted performance for a practical
four-junction solar cell.

| | | | I_{SC} | | |
|---|---|---|---|---|---|
| Subcell | E_{g} (eV) | D (μm) | (mA/cm²) | V_{OC} (V) | fill factor |
| ZnTe | 2.27 | 1.20 | 13.53 | 1.875 | 92% |
| ZnCdSeTe | 1.71 | 1.20 | 13.65 | 1.285 | 89% |
| AlGaAsSb | 1.32 | 1.70 | 14.68 | 0.882 | 86% |
| GaSb | 0.72 | 1.10 | 25.78 | 0.390 | 75% |

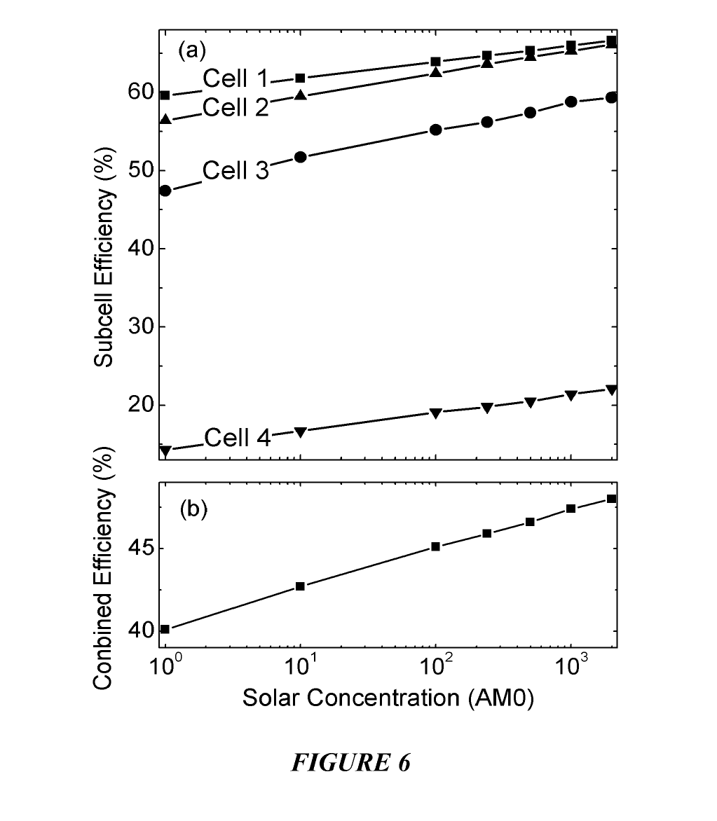

The performance of each individual subcell is simulated under the AM0 solar spectrum with concentrations from 1 to 2000 suns and is shown in FIG. 6(a). Losses due to contact shadowing are not considered. The conversion efficiency of an individual subcell is defined as the ratio of the power output of that subcell (under the working current, Iₘ) to the corresponding solar power absorbed by that subcell. For the practical design the efficiency of an individual subcell operating at the working current (Iₘ) of the entire solar cell is smaller in some cases than the maximum achievable due to the compromised bandgap selections.

The subcells with larger bandgap energies exhibit higher efficiencies. For example, in Table 3 the ZnTe subcell has both the highest efficiency and fill factor while the GaSb subcell has both the lowest efficiency and fill factor. This is an expected result as the fill factor is primarily determined by E_{g}/kT and when a subcell has a larger bandgap energy, the relative thermal relaxation loss is smaller, resulting in a higher efficiency. As shown in FIG. 6(b), the total AM0 conversion efficiency is above 40% under 1 sun, above 45% under 100 suns, and above 47% under 1000 suns. This is a substantial improvement over the reported record efficiencies of 30.6% under 1 sun AM0 for three junction solar cells. The practical design presented here is optimized for the AM0 solar spectrum; the optimal design is slightly different for various terrestrial solar spectra.

### Example 3

### 5-Junction Solar Cell

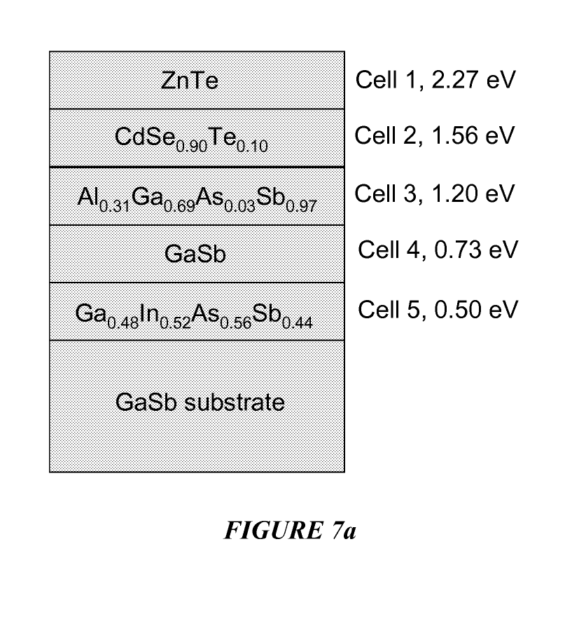

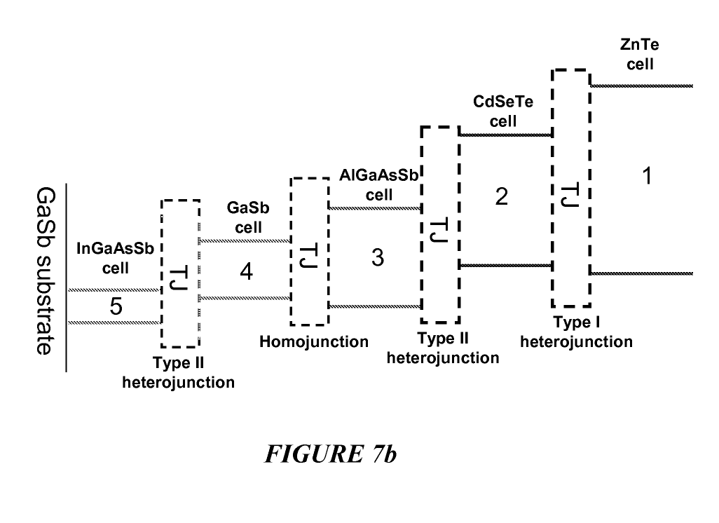

Based on the material properties discussed above, a novel 5-junction solar cell design for AM0 spectrum is shown in FIG. 7. This design uses binary, ternary, and quaternary alloys to reach the optimal bandgaps of all the multi junction building blocks while maintaining the lattice-matched condition. Fortunately for ZnTe and GaSb, not only are their lattice constants almost perfectly matched but also their bandgaps are very close to the ideal values of two different junctions required for this design. Small bandgap energy variations from the ideal values can be compensated for by optimizing the thicknesses of adjacent junctions. From a practical and cost saving point of view, the use of two binaries will dramatically reduce the number of growths necessary for calibrations.

The other important advantage of this material system is that the alloys can be doped both n- and p-type quite heavily, enabling the formation of the necessary tunnel junctions (see, Table 1, supra). It is well known that ZnSe and ZnTe are easily doped n-type [Ivanov, Phys. Stat. Sol. (a), 192, 157 (2002)] and p-type [Ozawa, et al., Appl. Phys. Lett., 64, 1120 (1994)], respectively, but p-type CdSe, ZnSe and n-type ZnTe are difficult to achieve [Chang et al., Appl. Phys. Lett., 79, 785 (2001); Katayama, et al., J. Cryst. Growth 214/215, 1064 (2000)]. It has however been demonstrated that the properties of alloys consisting of these binaries will have mixed properties for n- and p-type doping [Lin, et al., J. Appl. Phys., 84, 1472 (1998); Lin et al., J. Vac. Sci. Technol. B, 18, 1534 (2000)]. Both n- and p-type doping for antimonides is straightforward.

The practically-achievable conversion efficiencies of the proposed 5-junction design under AM0 solar spectrum for 1 and 500 suns are calculated using the commercial Silvaco software package and material parameters published in the literature. As listed in Table 4, the calculated results show that the conversion efficiency can reach 44% under one sun and 53% under 500 suns. These numbers are substantially larger than the reported values of the state-of-the-art 3-junction cells, 31% under 1 sun AM1.5D spectrum and 40.7% under 240 suns AM1.5D spectrum. As discussed above, the proposed material system also enables the construction of solar cell structures with even more junctions, such as 6 or 7, using lattice-matched quaternary alloys. This highly desirable feature is not believed to be available with any other known material systems that can be grown on any known substrates including GaAs or Ge.

TABLE 4
Simulation results of the 5-junction solar cell design

| | | | | | Efficiency |
|---|---|---|---|---|---|
| | | | I_{sc}(mA/A) | VOC (V) | (%) |
| | | | (1 sun/500 | (1 sun/500 | (1 sun/500 |
| Junction | Material | E_{g} (eV) | suns) | suns) | suns) |
| 1 | ZnTe | 2.27 | 14.1 mA/7.04 A | 1.97/2.13 | 19.7/21.6 |
| 2 | CdSe_{0.90}Te_{0.10} | 1.56 | 14.7 mA/7.33 A | 1.17/1.32 | 12.5/14.2 |
| 3 | Al_{0.31}Ga_{0.69}As_{0.03}Sb_{0.97} | 1.20 | 16.0 mA/8.00 A | 0.76/0.92 | 8.1/9.8 |
| 4 | GaSb | 0.73 | 19.3 mA/9.65 A | 0.30/0.46 | 3.2/4.9 |
| 5 | Ga_{0.48}In_{0.52}As_{0.56}Sb_{0.44} | 0.50 | 16.1 mA/8.09 A | 0.09/0.26 | 1.0/2.7 |

| | | | | |
|---|---|---|---|---|
| Complete 5-junction | — | — | — | 44/53 |

Table 4 reveals that the 5^{th} junction contributes very little under 1 sun. However, it contributes more to the overall efficiency under high concentration conditions such as 500 suns. This finding indicates that it is important to have junctions with IR bandgaps for high concentration applications.

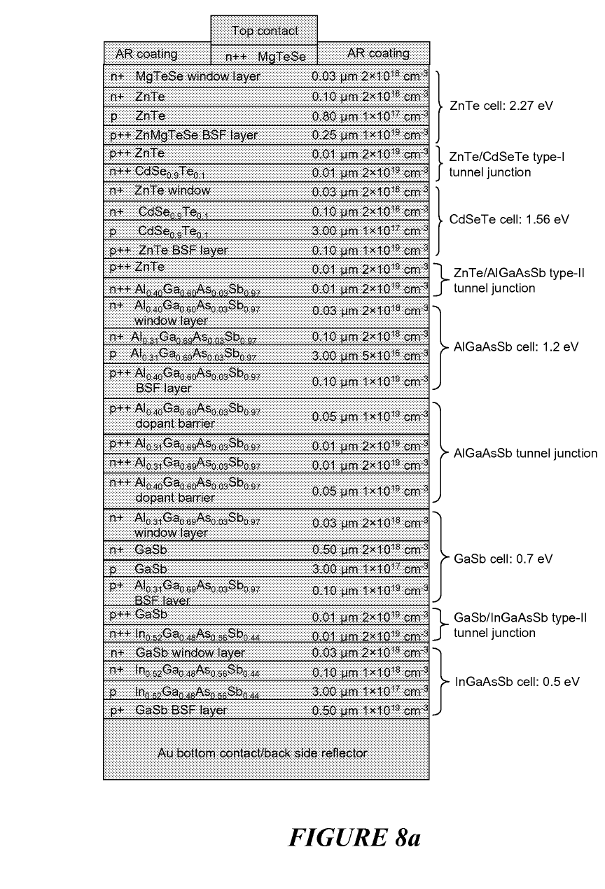

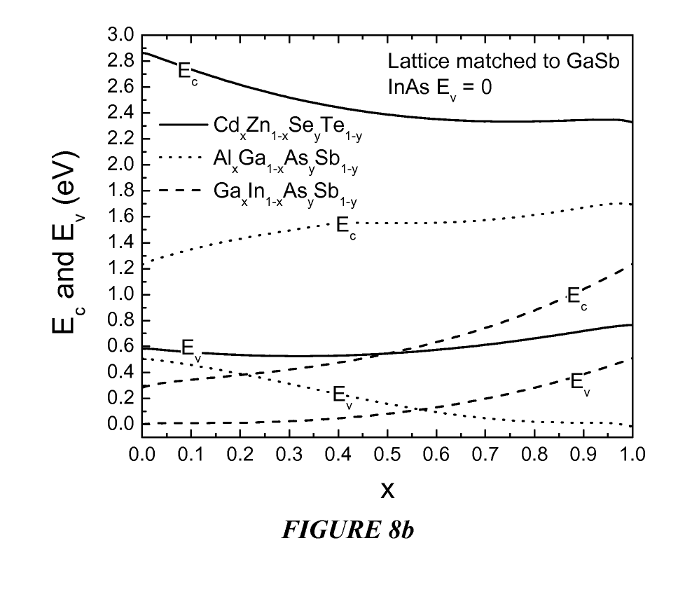

FIG. 8a shows a detailed device design of the proposed 5-junction solar cell, which has the following features: n⁺-MgSeTe is used as window and injection layer due to its wide bandgap and a high achievable doping concentration while ZnMgTeSe is used as the back surface field (BSF) layer. Only a small amount of Mg and Se will be incorporated to increase the bandgap just a little higher than that of ZnTe. The ZnTe/Al_{0.40}Ga_{0.60}As_{0.03}Sb_{0.97} tunnel junction consists of a type-II heterostructure, providing low series resistance. Two wide-bandgap Al_{0.40}Ga_{0.60}As_{0.03}Sb_{0.97} diffusion stop-layers are introduced to minimize the diffusion of dopants in the Al_{0.31}Ga_{0.69}As_{0.03}Sb_{0.97} tunnel junction. The GaSb/In_{0.52}Ga_{0.48}As_{0.56}Sb_{0.44} tunnel junction uses also an advantageous type-II heterostructure. GaSb is used as the window and the BSF layer for the In_{0.52}Ga_{0.48}As_{0.56}Sb_{0.44} cell. Au and p-type GaSb easily form a non-alloyed ohmic contact with high reflectivity so that it can reflect the below bandgap IR light back into the free space to reduce heat load.

Based on the conduction band edge and valence band edge diagram of ZnCdTeSe, AlGaAsSb, and InGaAsSb alloys shown in FIG. 8b, one can easily determine the band edge alignment between any two given layers of either different compositions or different materials. For example, the conduction band edge of AlGaAsSb (upper dot line) always lies in the middle of ZnCdTeSe bandgap (two solid lines) while the valance band edge of AlGaAsSb (lower dot line) always lies below the ZnCdTeSe valance band edge. Any ZnCdTeSe/AlGaAsSb heterojunction has therefore type-II band edge alignment.

Although there are other substrates, such as InP and InAs, on which one can also grow lattice-matched materials covering the whole solar spectrum, this patent application chooses GaSb as the example because we can find two binaries having almost the same lattice constants and people have demonstrated high performance GaSb solar cells as well. Efficiencies above 30% were reported [Fraas, et al., IEEE Trans. Electron Devices, 37, 443 (1990)] for GaSb and GaAs mechanically stacked solar cells. It is important to note that high performance GaSb PV cells were also developed in the past decade for thermal photovoltaic (TPV) applications. An important feature of TPV cells is that a high power density output up to 5 Wcm⁻² is expected [Bett and Sulima, Semiconductor Sci. Technol. 18, 5184 (2003)]. This value corresponds to an output of a concentrator solar cell under 250-500 suns. It is therefore reasonable to expect that GaSb is a mature material for solar cells.

Since a multi junction solar cell will operate under concentrations up to 1000 suns, the generated photocurrent can be as high as tens of A/cm². Therefore, the tunnel junctions must operate in the tunneling (linear) I-V region with a peak tunneling current (Jₚₑₐₖ) greater than the maximum current generated in the solar cells. In order to accomplish this, the tunnel junction must be highly doped and very thin. In this program, δ-doping will be used to give even lower series resistances of the tunnel junctions. This is quite important for concentrator solar cells, especially when a large number of junctions are used. Theoretical modeling using the material parameters given above show that the voltage drop of the tunnel junctions made by using the highest doping levels given in Table 4 should be very small.

### Example 4

### 6-Junction Solar Cell

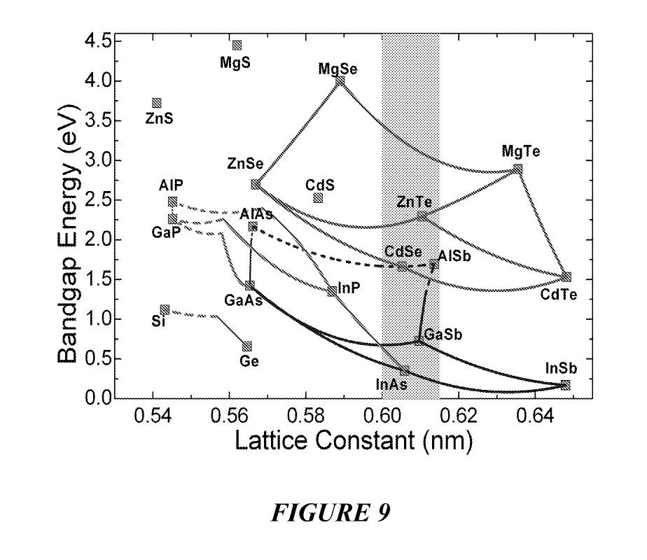

II/VI (ZnCdMg)(SeTe) and III/V (InAlGa)(AsSb) direct bandgap can be used as a material systems for MJ solar cells that can be grown lattice-matched on GaSb or InAs substrates. FIG. 9 shows the energy bandgaps of various II/VI and III/V alloys as a function of the lattice constant. One can find zinc blende structure direct bandgap II/VI and III/V quaternary alloys that cover the entire solar spectrum from 3.0 eV down to 0.4 eV and below and thus offer the flexibility for solar cell designs with optimal bandgap energies while maintaining the lattice-matched condition and consequently enabling designs with a large number of junctions. This material system may address all the challenges for ultrahigh efficiency MJ solar cells mentioned above and therefore has great potential to offer breakthroughs in conversion efficiency.

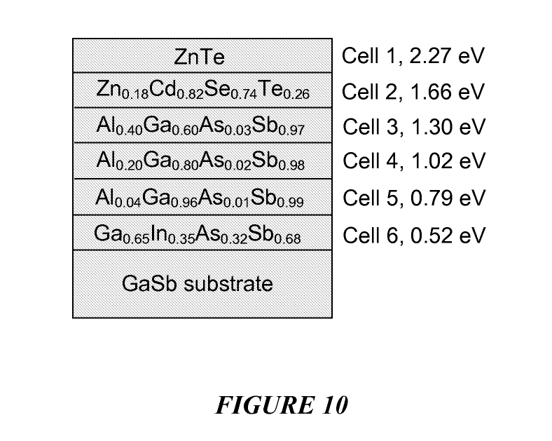

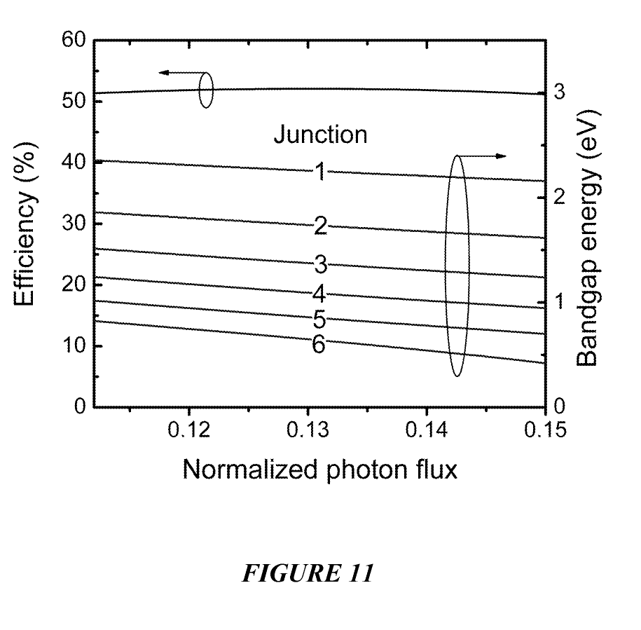

A 6-junction solar cell design is shown in FIG. 10. The bandgap energies of all of the subcells are chosen such that the current generated in each is perfectly matched to the next. FIG. 11 shows the ideal bandgap for each individual junction as a function of normalized photon flux in vicinity of 1 sun for the 6-junction design and the theoretical conversion efficiency limit, calculated using Henry's model [see, Henry, J. Appl. Phys. 51, 1980, pp. 4494-4500]. The efficiency limit is relatively flat as a function of photon flux. This characteristic enables a greater flexibility in choosing the set of bandgap energies for the entire solar cell without suffering substantial degradation of the overall device performance. It also indicates that the MJ solar cell performance is maintained even when the photon flux varies more than 50%, offering robust performance under different concentration ratios. Small bandgap energy variations from the ideal values can be also compensated for by optimizing the thicknesses of adjacent junctions to maintain the perfect current matching condition.

The thermodynamic limits discussed above are calculated using an ideal diode model and are therefore not achievable with practical device materials. We utilized the commercial Silvaco software package to simulate a more realistic device performance using the material parameters listed in Table 5. The physical model used by Silvaco takes into account limited carrier mobilities and radiative and non-radiative combination. To make a fair comparison with commercial products, 5% of the wafer surface area is assumed to be shaded by metal contacts. Since the current density is relatively small, the voltage drop across the tunnel junctions and the ohmic contacts are expected to be small and are not considered in this preliminary study, which therefore gives an upper bound of the achievable conversion efficiency limits.

TABLE 5
List of material parameters for the 6-junction solar cell design; J1, J2, J3, J4,
J5, J6 are ZnTe, Zn_{0.18}Cd_{0.82}Se_{0.74}Te_{0.26}, Al_{0.40}Ga_{0.60}As_{0.03}Sb_{0.97}, Al_{0.20}Ga_{0.80}As_{0.02}Sb_{0.98},
Al_{0.04}Ga_{0.96}As_{0.01}Sb_{0.99}, In_{0.35}Ga_{0.65}As_{0.32}Sb_{0.68}, respectively.

| | Symbol | | | | | | |
|---|---|---|---|---|---|---|---|
| Parameters | (unit) | J1 | J2 | J3 | J4 | J5 | J6 |
| Bandgap | E_{g} (eV) | 2.27 | 1.66 | 1.30 | 1.02 | 0.79 | 0.52 |
| energy | | | | | | | |
| Effective | mₑ* (m₀) | 0.117 | 0.117 | 0.083 | 0.067 | 0.052 | 0.037 |
| electron | | | | | | | |
| mass | | | | | | | |
| Effective | mₕ* (m₀) | 0.721 | 0.628 | 0.462 | 0.442 | 0.424 | 0.441 |
| hole mass | | | | | | | |
| Electron | μₙ | 1000 | 915 | 6979 | 8937 | 10736 | 25900 |
| mobility | (cm²/V/s) | | | | | | |
| Hole | μₚ | 120 | 55 | 742 | 843 | 937 | 784 |
| mobility | (cm²/V/s) | | | | | | |
| Electron | τₙ (s) | 10⁻⁷ | 10⁻⁷ | 10⁻⁷ | 10⁻⁷ | 10⁻⁷ | 6.05 · 10⁻⁸ |
| Lifetime | | | | | | | |
| Hole | τₚ (s) | 10⁻⁷ | 5 · 10⁻⁹ | 5 · 10⁻⁹ | 5 · 10⁻⁹ | 1.5 · 10⁻⁶ | 9.74 · 10⁻⁷ |
| Lifetime | | | | | | | |
| Radiative | B (cm³/s) | 1.89 · 10⁻¹⁰ | 10⁻¹⁰ | 10⁻¹⁰ | 10⁻¹⁰ | 10⁻¹⁰ | 2.18 · 10⁻¹⁰ |
| coefficient | | | | | | | |
| Auger | C (cm⁶/s) | | 5.0 · 10⁻³⁰ | 5 · 10⁻³⁰ | 5 · 10⁻³⁰ | 5 · 10⁻³⁰ | 1 · 10⁻²⁶ |
| coefficient | | | | | | | |
| Index of | n and κ | [18] | [15] | [15] | [15] | [15] | [15] |
| refraction | | | | | | | |

The modeling results are summarized in Table 6. The overall achievable energy conversion efficiency limits of this design are 43% under 1 sun AM0 condition and 52% under 240 suns, respectively. The contribution of each individual junction to the overall conversion efficiency depends on the material bandgap energy. As expected, the wider bandgap junctions contribute more to the overall power output. The 6^{th} junction contributes very little under 1 sun; however, it contributes more to the overall efficiency under high concentrations such as 240 suns. This finding indicates that it is important to have junctions with IR bandgaps for high concentration applications and that it is therefore necessary to integrate the II/VI materials with III/V layers.

TABLE 6
Simulation results of the 6-junction solar cell design using the Silvaco
software package under AM0 solar spectrum. The predicted conversion efficiencies
give the upper bound of the “achievable limits” because the realistic material
parameters are used for the simulation.

| | | | Jₘ (mA or | | |
|---|---|---|---|---|---|
| | | | A/cm²) | Vₘ (V) | Efficiency (%) |
| | | | (1 sun/240 | (1 sun/240 | (1 sun/240 |
| Junction | Material | Eg (eV) | suns) | suns) | suns) |
| 1 | ZnTe | 2.27 | 13.0/3.11 | 1.73/1.87 | 16.5/17.8 |
| 2 | Zn_{0.18}Cd_{0.82}Se_{0.74}Te_{0.26} | 1.66 | 13.0/3.11 | 1.12/1.28 | 10.7/12.2 |
| 3 | Al_{0.40}Ga_{0.60}As_{0.03}Sb_{0.97} | 1.30 | 13.0/3.11 | 0.81/0.96 | 7.71/9.16 |
| 4 | Al_{0.20}Ga_{0.80}As_{0.02}Sb_{0.98} | 1.02 | 13.0/3.11 | 0.55/0.70 | 5.24/6.68 |
| 5 | Al_{0.04}Ga_{0.96}As_{0.01}Sb_{0.99} | 0.79 | 13.0/3.11 | 0.32/0.47 | 3.05/4.48 |
| 6 | In_{0.35}Ga_{0.65}As_{0.32}Sb_{0.68} | 0.52 | 13.0/3.11 | 0.02/0.13 | 0.15/1.24 |
| — | All Junctions in | — | 13.0/3.11 | 4.55/5.41 | 43/52 |
| | Series | | | | |

The proposed material systems enable the construction of monolithically integrated solar cells with even more junctions, such as 7 or more, which may further increase the conversion efficiency. To the best of our knowledge, this highly desirable feature is not available with any other material system that can be grown lattice matched on any known commercial substrates. It is therefore very reasonable to expect that the proposed MJ solar cells will have great potential for both space and terrestrial applications.

The other important advantage of these material systems is that the alloys can be heavily doped both n- and p-type, enabling the formation of the necessary tunnel diodes. Table 1 (supra) lists most commonly used dopants and their maximum doping concentrations achieved in the binaries. It is well known that ZnSe and ZnTe are easily doped n-type [see, Ivanov, Phys. Status Solidi A, 192, 2002, pp. 157-165] and p-type [see, Ozawan et al., Appl. Phys. Lett. 64, 1994, pp. 1120-1122], respectively, but p-type CdSe, ZnSe and n-type ZnTe are difficult to achieve [see, Chang et al., Appl. Phys. Lett. 79, 2001, pp. 785-787; Katayama et al., J. Cryst. Growth, 214/215, 2000, pp. 1064-1070]. It has, however, been demonstrated that the properties of alloys consisting of these binaries have mixed properties for n- and p-type doping [see, Lin et al., J. Appl. Phys. 84, 1998, pp. 1472-1475; and Lin et al., J. Vac. Sci. Technol. B, 18, 2000, pp. 1534-1537]. Both n- and p-type doping in antimonides are straightforward. Table 2 (supra) lists metals used to form ohmic contacts on GaSb and ZnTe.

It is important to point out that the proposed II/VI (ZnCdMg)(SeTe) material system is different from the II/VI (ZnCd)(SSe) material system grown on GaAs substrates. The latter has been thoroughly studied for blue lasers, where the ZnSe buffer layer and the ZnSSe/ZnCdSe/ZnSSe quantum-well active region are not perfectly lattice matched to GaAs substrates, which results in misfit dislocations that drastically shorten the lifetime of blue lasers under very high current injection. In contrast, the presently proposed material systems are perfectly lattice matched to GaSb or InAs substrates, resulting in few misfit dislocations in the epitaxial layers. In addition, the current density of the solar cells is very low, less than 13 A/cm² even under 1000 suns, which is orders of magnitude lower than that (>1000 A/cm²) in blue semiconductor lasers. Therefore, it is very reasonable to expect that there should be no material reliability issues for the solar cells made of II/VI material system (ZnCdMg)(SeTe).

To the best of our knowledge, people have not explored the proposed approach for solar cells, although II/VI (ZnCdMg)(SeTe) and III/V (InGaAl)(AsSb) alloys have been studied very extensively for photodetectors and light emitting devices such as LEDs and lasers in the past decades. Compared with the current state-of-the-art MJ solar cell designs, the proposed structures have the following advantages such as: i) their direct bandgap energies and lattice-matched condition allow tandem cells to contain a large number of junctions with ultrahigh conversion efficiency; and ii) the direct-indirect band crossover for AlGaAsSb alloys offers materials with large absorption coefficients above the Γ valley so that the photogenerated carriers can thermally relax to the indirect valleys, resulting in longer lifetimes and potentially even greater V_{oc}. The new approach can also cover a much broader infrared region. It is therefore easy to add more junctions below the GaSb bandgap. Under high concentration, such as 500 to 2000 suns, those junctions in the IR region can further add to the overall energy conversion efficiency. AlGaAsSb/ZnCdSeTe and GaInAsSb/GaSb form type-II heterostructures, which offer the best tunnel junction with very low voltage drops. One of the most important features of the new design is its effective surface/interface passivation. In theory, these lattice-matched material systems offer unlimited selection of wider bandgap materials to be used as barriers to prevent minority carriers from reaching certain interfaces or surfaces where they parasitically recombine non-radioactively.

The proposed structures can be grown by both MBE and MOCVD. The former offers great flexibility and accurate control of layer thickness and interface quality, while the latter offers low-cost, higher throughput, and short downtime, making it more suitable for large-scale manufacturing. In our recent experimental studies of MBE grown ZnTe and ZnTe/ZnCdTe quantum wells on GaSb and InAs substrates, these materials exhibit very strong photoluminescence and narrow x-ray diffraction peaks, indicating excellent crystalline properties.

### Example 5

### Substrate Removal

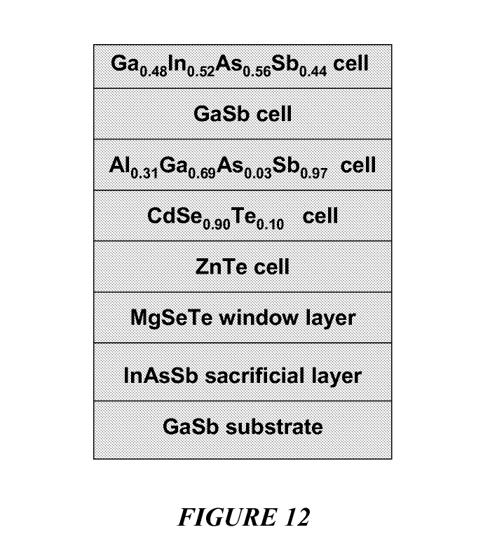

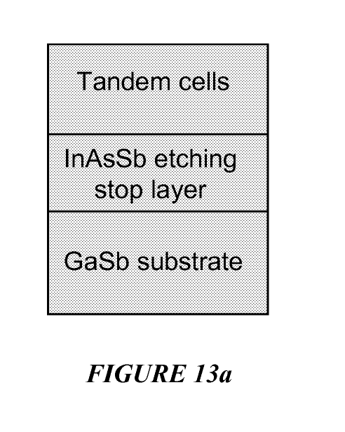

Removal of the substrate may reduce the series resistance and the absorption of infrared solar radiation that passes through all of the junctions. Further, substrate removal allows for placing a metal contact underneath the fifth junction so that the infrared radiation can be reflected back into free space and the series resistance generated by the substrate will be eliminated. FIG. 12 shows a proposed structure, which is in principle the same structure shown in FIG. 7 but with reverse layer sequence and an InAsSb sacrificial layer for substrate removal processes. This structure will be referred to as the “reversed structure” while the one shown in FIG. 7 will be referred to as the “normal structure” below.

Both layer structures have their own advantages and challenges. For the “normal structure” shown in FIG. 7, the growth sequence is compatible with the requirements for material growth temperatures as the listed II-VI materials typically require much lower growth temperatures than those for III-V's. From the processing point of view, the “reversed structure” shown in FIG. 12 is more attractive because it involves a simpler thin film transfer process to remove substrate.

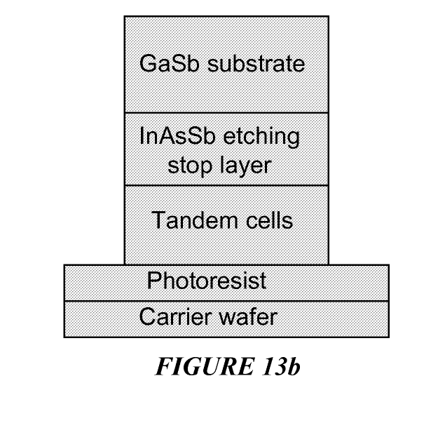

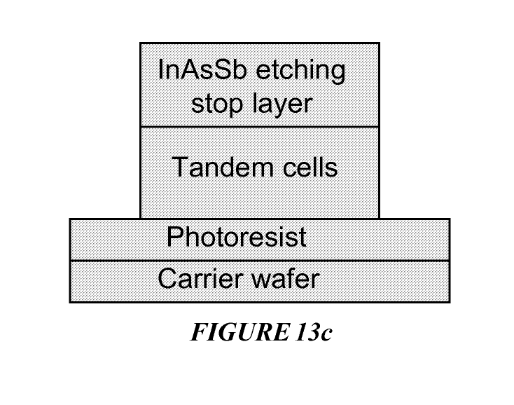

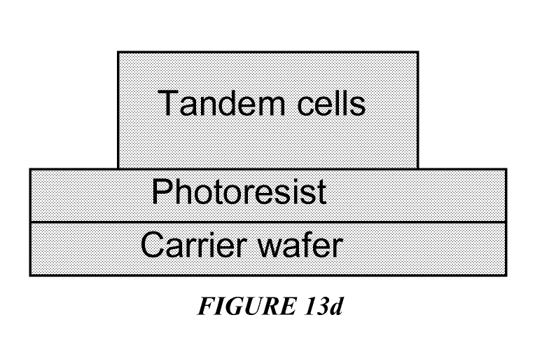

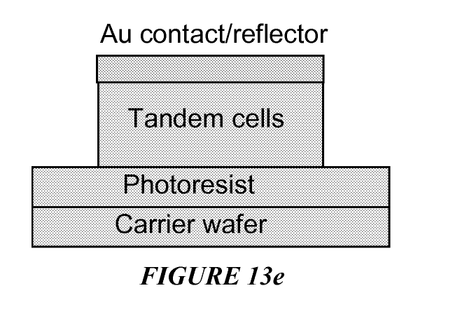

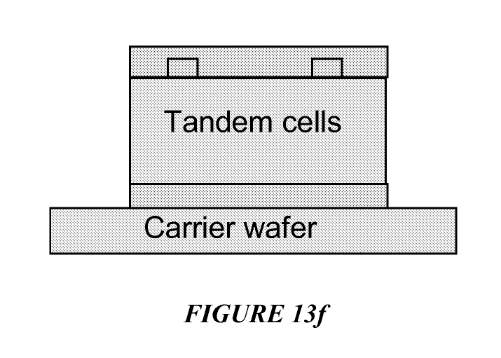

FIGS. 13a-13f, consecutively, show a detailed stepwise process for a substrate removal procedure. The GaSb substrate removal process is well developed using H₂O₂:H₂O:NaK spin etching or CrO₃:HF:H₂O to selectively etch GaSb. InAsSb can be etched by Citric Acid:H₂O₂. [see, Wang, J. Cryst. Growth, 272, 664 (2004)]The top layer of the exposed tandem cell is p-type GaSb, on which it is easy to form ohmic contacts with a series of metals such as Au, Cr, Ni. A thick Au layer is chosen to serve as an IR reflector and a good heat-spreading layer.

The present invention is illustrated by way of the foregoing description and examples. The foregoing description is intended as a non-limiting illustration, since many variations will become apparent to those skilled in the art in view thereof. It is intended that all such variations within the scope and spirit of the appended claims be embraced thereby. Each referenced document herein is incorporated by reference in its entirety for all purposes.

Changes can be made in the composition, operation and arrangement of the method of the present invention described herein without departing from the concept and scope of the invention as defined in the following claims.

We claim:

1. A semiconductor structure comprising a substrate and at least two multi-junction building blocks formed over the substrate, wherein
the substrate is a III-V substrate or a II-VI substrate; and
each multi junction building block independently comprises a p-n junction having at least two alloy layers, wherein the alloy layers are independently III-V or II-VI alloy layers, wherein one alloy layer is p-doped and the other alloy layer is n-doped,
provided at least one multi junction building block comprises II-VI alloy layers.

2. The structure of claim 1, wherein the III-V substrate comprises GaSb, InAs, or InP.

3. (canceled)

4. The structure of claim 1, wherein the II-VI substrate comprises CdSe, CdTe, or ZnTe.

5. The structure of claim 1, wherein the multi-junction building blocks are lattice matched or pseudomorphically strained to the substrate.

6. The structure of claim 1, wherein each multi junction building block further comprises a third layer of the same or different alloy as the p-n junction, and the third layer is p⁺, P, n⁺, or N doped.

7. (canceled)

8. (canceled)

9. (canceled)

10. (canceled)

11. The structure of claim 1, wherein each III-V alloy layer independently comprises a binary, ternary, or quaternary (InGaAl)(AsSbP) alloy.

12. (canceled)

13. The structure of claim 1, wherein each II-VI alloy layer independently comprise a binary, ternary, or quaternary (ZnCdHgBeMg)(SeTe) alloy.

14. (canceled)

15. (canceled)

16. (canceled)

17. (canceled)

18. (canceled)

19. (canceled)

20. (canceled)

21. (canceled)

22. The structure of claim 1, further comprising at least one tunnel junction.

23. (canceled)

24. The structure of claim 1, further comprising a buffer layer between the substrate and the first multi-junction building block foamed over the substrate.

25. The structure of claim 1, wherein each of multi junction building blocks has a bandgap greater than the multi-junction building block it is formed over.

26. The structure of claim 1, wherein each of multi junction building blocks has a bandgap less than the multi junction building block it is formed over.

27. A method for preparing a semiconductor structure comprising,
preparing an etch-stop ternary III-V alloy layer over an III-V substrate;
preparing at least two multi junction building blocks over the etch-stop layer, wherein each multi junction building block independently comprises a p-n junction having at least two alloy layers, wherein the alloy layers are independently III-V or II-VI alloy layers, wherein one alloy layer is p-doped and the other alloy layer is n-doped, provided at least one multi junction building block comprises II-VI alloy layers;
removing the substrate; and
removing the etch-stop alloy layer.

28. The method of claim 27, wherein the III-V substrate comprises GaSb, InAs, or InP.

29. (canceled)

30. (canceled)

31. (canceled)

32. (canceled)

33. (canceled)

34. The method of claim 27, wherein each multi junction building block further comprises a third layer of the same or different alloy as the p-n junction, and the third layer is p⁺, P, n⁺, or N doped.

35. (canceled)

36. (canceled)

37. (canceled)

38. (canceled)

39. The method of claim 27, wherein each III-V alloy layer independently comprises a binary, ternary, or quaternary (InGaAl)(AsSbP) alloy.

40. (canceled)

41. The method of claim 27, wherein each II-VI alloy layer independently comprises a binary, ternary, or quaternary (ZnCdHgBeMg)(SeTe) alloy.

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. A semiconductor structure comprising at least two multi junction building blocks, wherein
each multi junction building block independently comprises a p-n junction having at least two alloy layers, wherein the alloy layers are independently III-V or II-VI alloy layers, wherein one alloy layer is p-doped and the other alloy layer is n-doped,
provided at least one multi junction building block comprises II-VI alloy layers.

56. The structure of claim 55, wherein each multi-junction building block further comprises a third layer of the same or different alloy as the p-n junction, and the third layer is p⁺, P, n⁺, or N doped.

57. (canceled)

58. The structure of claim 55, wherein each of the multi junction building blocks is lattice matched or pseudomorphically strained to the substrate.

59. (canceled)

60. (canceled)

61. (canceled)

62. The structure of claim 55, wherein each III-V alloy layer independently comprises a binary, ternary, or quaternary (InGaAl)(AsSbP) alloy.

63. (canceled)

64. The structure of claim 55, wherein each II-VI alloy layer independently comprises a binary, ternary, or quaternary (ZnCdHgBeMg)(SeTe) alloy.

65. (canceled)

66. The structure of claim 55, wherein the bandgap of each of the multi junction building block is 0.50-3.00 eV.

67. (canceled)

68. (canceled)

69. (canceled)

70. (canceled)

71. (canceled)

72. (canceled)

73. The structure of claim 55, further comprising at least one tunnel junction.

74. (canceled)

75. The structure of claim 55, wherein each of multi junction building blocks has a bandgap greater than the multi junction building block it is formed over.

76. The structure of claim 55, wherein each of multi junction building blocks has a bandgap less than the multi junction building block it is formed over.

77. (A method for preparing a semiconductor structure comprising
forming at least two multi junction building blocks over a substrate, wherein
the substrate is a III-V substrate or a II-VI substrate; and
each multi junction building block independently comprises a p-n junction having at least two alloy layers, wherein the alloy layers are independently III-V or II-VI alloy layers, wherein one alloy layer is p-doped and the other alloy layer is n-doped,
provided at least one multi junction building block comprises II-VI alloy layers.

78. (canceled)

79. The method of claim 77, wherein the III-V substrate comprises GaSb, InAs, or InP.

80. (canceled)

81. The method of claim 77, wherein the II-VI substrate comprises CdSe, CdTe, or ZnTe.

82. (canceled)

83. The method of claim 77, wherein each multi-junction building block further comprises a third layer of the same or different alloy as the p-n junction, and the third layer is p⁺, P, n⁺, or N doped.

84. (canceled)

85. (canceled)

86. (canceled)

87. (canceled)

88. The method of claim 77, wherein each III-V alloy layer independently comprises a binary, ternary, or quaternary (InGaAl)(AsSbP) alloy.

89. (canceled)

90. The method of claim 77, wherein each II-VI alloy layer independently comprise a binary, ternary, or quaternary (ZnCdHgBeMg)(SeTe) alloy.

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)
